(19) United States
(12) Patent Application Publication
(10) Pub. No.: US 2014/0231977 A1
(43) Pub. Date: Aug. 21, 2014

(54) SEMICONDUCTOR PACKAGES WITH LOW STAND-OFF INTERCONNECTIONS BETWEEN CHIPS

(71) Applicants: Navas Khan Oratti Kalandar, Petaling Jaya (MY); Chee Seng Foong, Sg Buloh (MY); Kesvakumar V.C. Muniandy, Klang (MY)

(72) Inventors: Navas Khan Oratti Kalandar, Petaling Jaya (MY); Chee Seng Foong, Sg Buloh (MY); Kesvakumar V.C. Muniandy, Klang (MY)

(21) Appl. No.: 13/773,578

(22) Filed: Feb. 21, 2013

(51) Int. Cl. H01L 23/498; H01L 21/78; H01L 23/495; H01L 21/56

(52) U.S. Cl. CPC H01L 23/49811; H01L 21/565; H01L 21/78; H01L 23/495
USPC 257/676; 438/107; 438/113; 257/737

(57) ABSTRACT

A method of forming a semiconductor package includes providing a support and a first semiconductor die, each having first and second main surfaces. The second main surface of the first die is disposed on the first main surface of the support. Stud bumps are formed on the first main surface of the first die. A surface of a second semiconductor die is bonded to the stud bumps. The first main surface of the first die is wire bonded to the first main surface of the support. The first and second dies, the stud bumps, the bond wire, and at least a portion of the first main surface of the support are encapsulated with a mold compound.

### BACKGROUND OF THE INVENTION

The present invention is directed to a semiconductor package and, more particularly, to semiconductor packages with low stand-off interconnections between chips.

Multi-functional semiconductor dies, for example microcontroller units (MCUs), microprocessor units (MPUs), memory, and the like, often are packaged with other circuits together in order to produce better system integration and to reduce component size. One conventional method stacks multiple dies in a package and provides bond wires between each die and the supporting substrate or lead frame. This solution can result in lengthy interconnection paths and large package surface areas.

Another type of structure, such as a “flip-chip” or a “chip-to-chip” configuration, allows interconnection among the dies. For example, a base die is connected directly to a top die through solder bumps, copper pillars, or the like, and the base die is wire bonded to the substrate. In this way, a smaller package can be achieved because the wires connecting the top die to the substrate are not present. However, this configuration is not without its disadvantages.

In particular, this configuration can be very costly due to the increase in manufacturing steps and materials. For example, copper pillaring itself is an expensive and time-consuming process. As for the solder bump configuration, many semiconductor dies use bonding pads containing aluminum for making the electrical connections. While aluminum makes a good electrical conductor, the material is not compatible with most solder materials. Thus, before the solder bumps can be bonded to the aluminum pads, the pads must undergo an under bump metallization (UMB) process or the like so that the solder bumps will adequately bond to the aluminum pads.

In addition, formation of solder bumps on the top and/or base dies typically occurs at the wafer-level, i.e., prior to singulation of the individual dies. This subjects the bumps to further processing, increasing the risk and amount of oxidation and other intermetallic compound (IMC) formations. Still further, soldering processes require the use of solder masks, again adding to the cost and materials needed for manufacture.

It is therefore desirable to provide a semiconductor package with a low stand-off and low manufacturing costs.

### BRIEF DESCRIPTION OF THE DRAWINGS

The present invention is illustrated by way of example and is not limited by embodiments thereof shown in the accompanying figures, in which like references indicate similar elements. Elements in the figures are illustrated for simplicity and clarity and have not necessarily been drawn to scale. Notably, certain vertical dimensions have been exaggerated relative to certain horizontal dimensions.

In the drawings:

FIG. 1 is a cross-sectional side elevational view of a plurality of semiconductor packages in accordance with an embodiment of the invention;

FIG. 2 is a bottom plan view of a wafer for manufacturing a second semiconductor die in accordance with an embodiment of the invention;

FIG. 3 is a cross-sectional side elevational view of a support and first semiconductor die provided for manufacturing a semiconductor package in accordance with an embodiment of the invention;

FIG. 4 is a cross-sectional side elevational view of the structure of FIG. 3 with stud bumps formed on the first semiconductor die;

FIG. 5 is a cross-sectional side elevational view illustrating a step of bonding the second semiconductor die to the structure of FIG. 4 in accordance with an embodiment of the invention;

FIG. 6 is a cross-sectional side elevational view of the structure of FIG. 5 following wire bonding of the first semiconductor die to the support in accordance with an embodiment of the invention; and

FIG. 7 is a cross-sectional side elevational view of the structure of FIG. 6 following encapsulation in accordance with an embodiment of the invention.

### DETAILED DESCRIPTION OF THE INVENTION

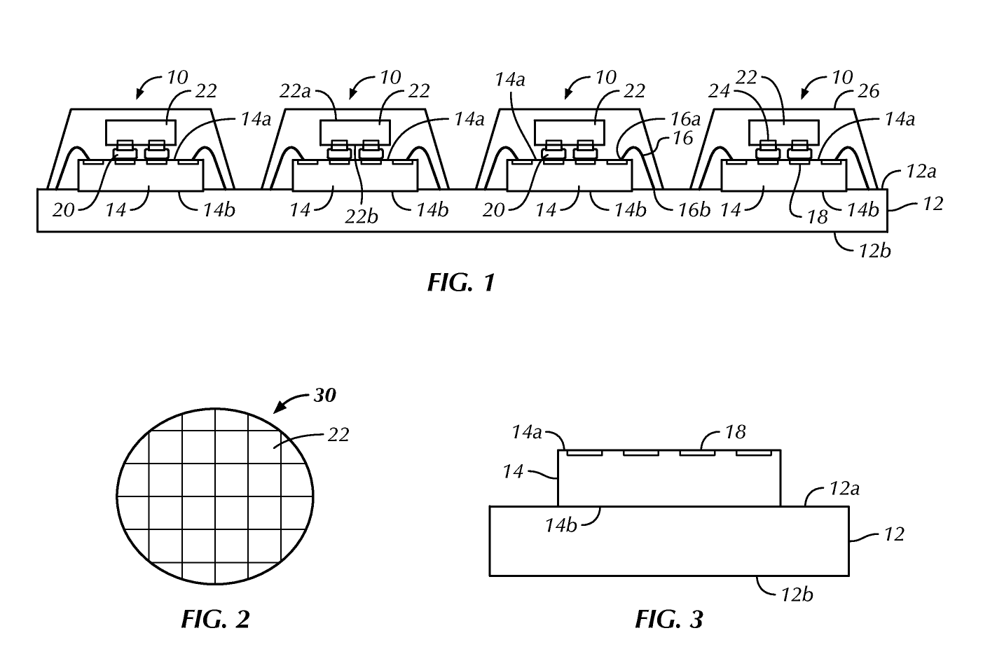

Referring to the drawings, wherein the same reference numerals are used to designate the same components throughout the several figures, there is shown in FIG. 1 a plurality of semiconductor packages 10 in accordance with an embodiment of the invention. Each package 10 includes a support 12 having opposing first and second main surfaces 12a, 12b. The support 12 may be singulated to form separate packages 10 or the support 12 may remain intact such that the packages 10 are used together. The support 12 may be a lead frame, in which case the support is preferably made from copper (Cu), aluminium (Al), or like conductive materials, although nonconductive materials or combinations thereof may be used as well.

The support 12 may alternatively be a laminate substrate, in which case the support 12 is preferably made from polymer-based materials, such as fiberglass, polyimide, or the like, although other types of materials may be used as well. In the case of a laminate substrate, a plurality of electrical conductors (not shown), in the form of copper traces or the like, may be formed on the first and/or second main surfaces 12a, 12b of the support 12. However, the electrical conductors may also be embedded or partially embedded in the support 12. The support 12 may further be coated with a protective layer (not shown), such as a lacquer-like layer of polymer that can be used to provide a permanent protective coating for the electrical conductors.

It should be noted that the support 12 is not so limited and may alternatively be comprised of other structures and include other materials than those described above.

Each package 10 further includes a first or base semiconductor die 14 having opposing first and second main surfaces 14a, 14b. The first semiconductor die 14 is preferably formed from any semiconductor material or combinations of materials, such as gallium arsenide, silicon germanium, silicon-on-insulator (SOI), silicon, monocrystalline silicon, the like, and combinations of the above. In the configuration shown in FIG. 1, the second main surface 14b of the first semiconductor die 14 is attached to the first main surface 12a of the support 12. The attachment is preferably made by epoxy or a like adhesive, although other methods of attachment, such as solder mounts, welding, mechanical or other fasteners, or the like, may be used as well.

In the configuration shown in FIG. 1, a plurality of first semiconductor dies 14 are mounted on the support 12. The support 12 shown in FIG. 1 may be subjected to further processing. For example, ball grid array (BGA) processing may be necessary to form solder balls (not shown) on the second main surface 12b of the support 12, which are configured to establish electrical connections with a printed circuit board (PCB) or the like.

Electrical connection between the first semiconductor die 14 and the support 12 is preferably made using at least one wire 16. Preferably, a first end 16a of the wire 16 is bonded to the first main surface 14a of the first semiconductor die 14 and a second end 16b of the wire 16 is bonded to the first main surface 12a of the support 12. However, other connection points for the wire 16 on the first semiconductor die 14 and the support 12 may be used as well. The wires 16 are preferably in the form of gold wires attached via a conventional wire bonding process, although other materials and attachment techniques may be used. Electrical interconnections between the support 12 and the first semiconductor die 14 may alternatively be made through other structures, such as solder balls or the like.

To facilitate the attachment of the wires 16, the first main surface 14a of the first semiconductor die 14 preferably includes pads 18 disposed on the first main surface 14a or at least partially embedded therein. The pads 18 are preferably formed of aluminum, although other materials exhibiting good electrical conductance may be used as well.

The pads 18 may also be used for the formation of one or more stud bumps 20 on the first main surface 14a of the first semiconductor die 14. The stud bumps 20 are preferably formed of a copper (Cu) material to enable the use of solder filler particles in an adhesive 32 (FIG. 5) to form a metallic joint with a second semiconductor die 22, described below. However, other conductive materials, such as gold (Au) or the like, may be used as well. The use of stud bumps 20 is advantageous over the prior art use of solder balls for electrical connection to the first semiconductor die 14 because metallization of the pads 18 is not required, thereby reducing manufacturing steps and cost. The use of stud bumps 20 also creates more reliable and lower cost connections than conventional methods.

The second or top semiconductor die 22 having first and second opposing main surfaces 22a, 22b is also provided. Like the first semiconductor die 14, the second semiconductor die 22 is preferably formed from any semiconductor material or combinations of materials, such as gallium arsenide, silicon germanium, silicon-on-insulator (SOI), silicon, monocrystalline silicon, the like, and combinations of the above.

The second main surface 22b of the second semiconductor die 22 preferably includes one or more electrical conductors 24, which may be disposed on the second main surface 22b or at least partially embedded therein. The electrical conductors 24 are preferably formed by an electroless nickel immersion gold (ENIG) process, elecroless tin plating, or the like. The electrical conductors 24 facilitate electrical connections to the stud bumps 20 on the first main surface 14a of the first semiconductor die 14. Through bonding of the electrical conductors 24 of the second main surface 22b of the second semiconductor die 22 to the stud bumps 20, electrical connection to the first semiconductor die 14 is established. Moreover, the stud bumps 20 may provide an indirect electrical connection for the second semiconductor die 22 to the support 12.

The package 10 further includes a mold compound 26 that is disposed on the first main surface 12a of the support 12 and encapsulates the first and second semiconductor dies 14, 22, the wires 16, and the stud bumps 20. The mold compound 26 may be made from a ceramic material, a polymeric material, or the like.

Additional dies (not shown) can also be added, prior to encapsulation, using the techniques described herein. For example, one or more additional dies may be attached to the first main surface 22a of the second semiconductor die 22 using additional stud bumps (not shown).

Referring now to FIGS. 2-7, an exemplary method for manufacturing a package 10 in accordance with an embodiment of the invention will now be described. In FIG. 2, a wafer 30 is shown from which the second semiconductor die 22 is eventually singulated. It is preferred that the electrical conductors 24 are formed on the second main surface 22b of the second semiconductor die 22 prior to singulation. Thus, electroless plating, such as the ENIG process, or other techniques for forming the electrical conductors 24, is performed at the wafer 30 level. The wafer 30 is thereafter singulated and can be coated with a conductive and/or nonconductive adhesive 32 (FIG. 5), such as flip-chip bonder, die bonder, or the like, depending on the method utilized for bonding the second semiconductor die 22.

Any or all steps in the preparation of the second semiconductor die 22 may take place before, simultaneously with, or after preparation of the support 12 and first semiconductor die 14 described below.

Referring to FIG. 3, the second main surface 14b of the first semiconductor die 14 is attached to the first main surface 12a of the support 12. The pads 18 on the first main surface 14a of the first semiconductor die 14 may be formed before or after attachment to the support 12.

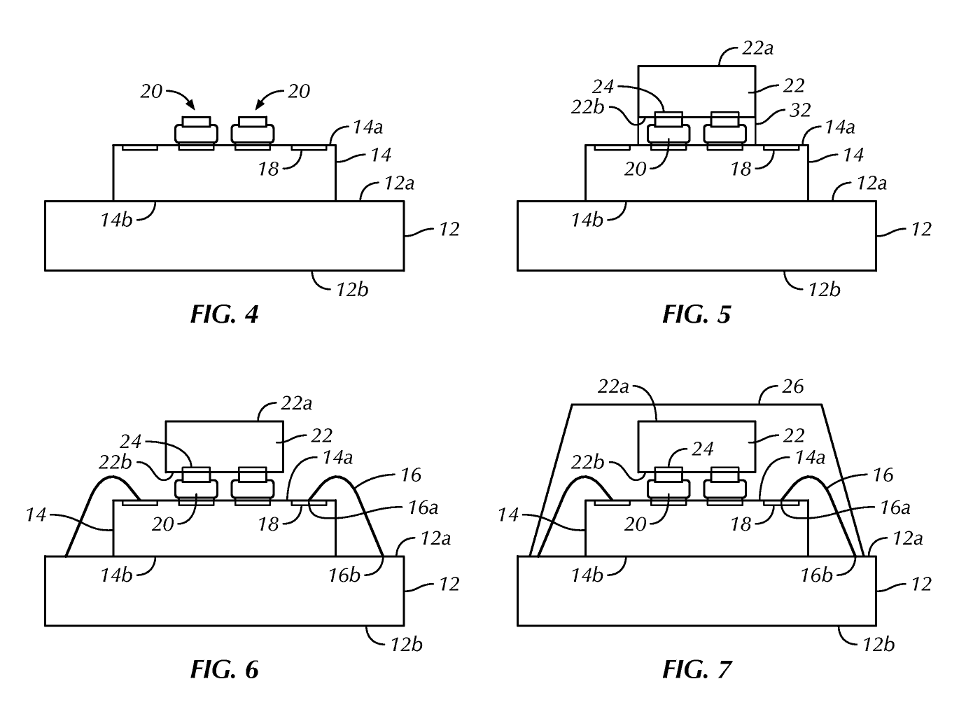

Referring to FIG. 4, the stud bumps 20 are formed on the first main surface 14a of the first semiconductor die 14, preferably mounted to pads 18 proximate a center region of the first main surface 14a of the semiconductor die 14. The stud bumps 20 may be formed by a conventional technique, wherein shaped metallic material is bonded to each of the pads 18, similar to wire bonding, but the wires (not shown) are each cut closely above the bonded material to form the studs. As previously described, this process does not require that the pads 18 be metallized, as the formation of the stud bumps 20 is compatible with aluminum, the common material for the pads 18, unlike solder.

While this process may be performed at the wafer level, it is preferred that the stud bumps 20 are formed after the first semiconductor die 14 has been singulated. The stud bumps 20 are therefore subjected to fewer processing steps than conventional connections to the first semiconductor die 14, which reduces oxidation and/or IMC formation on the stud bumps 20.

Referring to FIG. 5, the second main surface 22b of the second semiconductor die 22 is bonded to the stud bumps 20. The bonding may be performed by thermosonic bonding, thermo-compression bonding, or the like. As a result, a solder mask is not required for the electrical conductors 24. Following the bonding step, conventional wet and/or dry cleaning of the first and second semiconductor dies 14, 22 may be performed, including removal of excess adhesive 32, if necessary.

Referring to FIG. 6, the wires 16 are bonded to the first main surface 14a (preferably at the remaining pads 18) of the first semiconductor die 14 and the first main surface 12a of the support 12 using conventional wire bonding techniques. It is preferred that the wire bonding occur after the second semiconductor die 22 is bonded to the stud bumps 20, in order to avoid any damage to the wires 16 during the thermosonic bonding, thermo-compression bonding, or like process. However, it is contemplated that in some embodiments the wires 16 may be attached after the second semiconductor die 22 has been bonded to the stud bumps 20.

Referring to FIG. 7, the mold compound 26 is applied in a conventional manner and may be molded to fill the volume between the first and second semiconductor dies 14, 22, as well as encapsulate the first and second semiconductor dies 14, 22, the wires 16, and the stud bumps 20. At least a portion of the first main surface 12a of the support 12 is also preferably covered with the mold compound 26. However, the mold compound 26 may be selectively applied so as to leave certain components of the package 10 exposed for further processing and/or attachment to additional components. Subsequent steps for completing the package 10 to the desired specification, for example BGA formation on the second main surface 12b of the support 12, may thereafter be performed as needed.

As previously described, additional dies (not shown) may be attached to the second semiconductor die 22 using similar techniques prior to encapsulation.

In the foregoing specification, the invention has been described with reference to specific examples of embodiments of the invention. It will, however, be evident that various modifications and changes may be made therein without departing from the broader spirit and scope of the invention as set forth in the appended claims.

Those skilled in the art will recognize that boundaries between the above-described operations are merely illustrative. The multiple operations may be combined into a single operation, a single operation may be distributed in additional operations and operations may be executed at least partially overlapping in time. Further, alternative embodiments may include multiple instances of a particular operation, and the order of operations may be altered in various other embodiments.

The terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

In the claims, the word ‘comprising’ or ‘having’ does not exclude the presence of other elements or steps then those listed in a claim. Further, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The fact that certain measures are recited in mutually different claims does not indicate that a combination of these measures cannot be used to advantage.

1. A method of forming a semiconductor package, the method comprising:
providing a support having opposing first and second main surfaces and a first semiconductor die having opposing first and second main surfaces, the second main surface of the first semiconductor die being disposed on the first main surface of the support;
forming one or more metal stud bumps on the first main surface of the first semiconductor die;
bonding a surface of a second semiconductor die to the one or more stud bumps, the stud bumps providing an electrical connection between the first and second semiconductor dies, wherein the bonding of the second semiconductor die to the one or more stud bumps is performed by one of thermo-compression or thermosonic bonding;
wire bonding the first main surface of the first semiconductor die to the first main surface of the support with at least one wire to electrically connect the first semiconductor die and the support; and
encapsulating the first and second semiconductor dies, the one or more stud bumps, the at least one wire, and at least a portion of the first main surface of the support with a mold compound.

2. The method of claim 1, further comprising:
forming one or more electrical conductors on the second main surface of the second semiconductor die, each of the electrical conductors being configured for electrical connection to a corresponding one of the one or more stud bumps.

3. The method of claim 2, wherein the forming of the one or more electrical conductors includes electroless plating.

4. The method of claim 3, wherein the forming of the one or more electrical conductors include an electroless nickel immersion gold (ENIG) process.

5. The method of claim 2, wherein the forming of the one or more electrical conductors occurs before singulation of the second semiconductor die from a wafer.

6. The method of claim 1, further comprising:
forming one or more pads on the first main surface of the first semiconductor die, each of the one or more pads corresponding to one of the one or more stud bumps.

7. The method of claim 1, wherein the bonding of the second semiconductor die to the stud bumps includes application of an adhesive between the first and second semiconductor dies, and the adhesive includes a filler that forms an additional metallic connection to the stud bump.

8. The method of claim 1, wherein the step of providing a support and a first semiconductor die includes attaching the second main surface of the first semiconductor die to the first main surface of the support.

9. The method of claim 1, wherein the wire bonding occurs after the second semiconductor die is bonded to the one or more stud bumps.

10. (canceled)

11. A semiconductor package, comprising:
a support having opposing first and second main surfaces;
a first semiconductor die having opposing first and second main surfaces, the second main surface of the first semiconductor die being disposed on the first main surface of the support;
at least one wire having a first end bonded to the first main surface of the first semiconductor die and a second end bonded to the first main surface of the support, the at least one wire providing an electrical connection between the first semiconductor die and the support;
one or more metal stud bumps formed on the first main surface of the first semiconductor die;
a second semiconductor die having opposing first and second main surfaces, a portion of the second main surface of the second semiconductor die being bonded to the one or more stud bumps using one of thermo-compression or thermosonic bonding, the one or more stud bumps providing an electrical connection between the first and second semiconductor dies; and
a mold compound disposed on the first main surface of the support and encapsulating the first and second semiconductor dies, the at least one wire, and the one or more stud bumps.

12. The package of claim 11, further comprising one or more electrical conductors formed on the second main surface of the second semiconductor die, each of which corresponds to one of the one or more stud bumps.

13. The package of claim 12, wherein the one or more electrical conductors are formed of nickel immersed in a layer of gold.

14. The package of claim 12, wherein the one or more electrical conductors are formed of tin.

15. The package of claim 11, further comprising one or more pads formed on the first main surface of the first semiconductor die, each of which corresponds to one of the one or more stud bumps.

16. The package of claim 11, further comprising an adhesive between the first and second semiconductor dies for bonding the second semiconductor die to the stud bumps, wherein the adhesive includes a filler that forms an additional metallic connection to the stud bumps.

17. The package of claim 11, wherein the support is one of a lead frame or a laminate substrate.
